(19) United States
(12) Patent Application Publication
(10) Pub. No.: US 2006/0226546 A1
(43) Pub. Date: Oct. 12, 2006

(54) Alloy material for semiconductors, semiconductor chip using the alloy material and production method of the same

(76) Inventors: Kazunori Inoue, Kitakatsuragi-gun (JP); Chiharu Ishikura, Odawara-shi (JP)

Correspondence Address: BIRCH STEWART KOLASCH & BIRCH, PO BOX 747, FALLS CHURCH, VA, 22040-0747, US

(21) Appl. No.: 10/536,406

(22) PCT Filed: Oct. 29, 2003
(86) PCT No.: PCT/JP03/13890

§ 371 Date: Dec. 5, 2005

(30) Foreign Application Priority Data
Nov. 26, 2002 (JP) 2002-342797

(51) Int. Cl. H01L 29/40; H01L 21/44

(52) U.S. Cl. 257/741; 438/119; 438/686; 438/679; 257/768

(57) ABSTRACT

According to the present invention, there is provided an alloy material for semiconductors containing of Au as a main component and Ag in the range of not less than 3 wt % to not more than 40 wt %.

### TECHNICAL FIELD

The present invention relates to an alloy material for semiconductors, a semiconductor chip using the alloy material and a production method of the same. More particularly, the present invention relates to a AuAg alloy material, to a semiconductor chip in which the alloy material is used for stable performance of the chip and to a production method of the same.

### BACKGROUND ART

Conventionally, as metal materials for the production of semiconductor devices, Au or Ag has been used in single layer form in accordance with their use purport.

Au is generally a metal material that is stable in the air and has good elongation. Au does not react with components in the atmosphere or other materials even when it is heated and can maintain a clean metal surface. Also, Ag is inexpensive and has a low resistance. For the above reasons, Au has been frequently used as a metal material for semiconductors.

However, when a Au film is directly applied onto a Si layer, it may cause degradation in film properties, because Si diffuses into Au due to a heating treatment which is performed after the application, making the composition of the Au film unstable.

Ag, when used as a single metal film, is liable to sulfurize, and recrystallizes and softens by self-annealing.

Under such circumstances, there has been proposed, for example, use of an alloy material containing Ag as a main component, 0.1 wt %-10 wt % of Au, and at least one of elements such as Cu, Al, Ti and the like respectively in an amount not less than 0.1 wt % to not more than 5 wt %, as a AuAg containing alloy material in electronic components, electronic hardware, electro-optical components and the like (for example, see Japanese Unexamined Patent Publication No. 2002-140929). Such an alloy material, that is, an alloy material having Cu, Al and/or Ti contained in Au and Ag has an improved stability and workability and is used for decreasing the resistance of wires.

There are also methods using sputtering, for example, a method in which Au and Ag, which are single metals, are formed into a mosaic and used as a target material to form an alloy layer of Au and Ag; and a method in which Au and Ag, which are single metals, are used as individual target materials to form a multilayer film of a Au film and a Ag film and then the two films are diffused to form an alloy layer of Au and Ag.

The alloy layers formed using such targets, however, can not be uniform, resulting in a problem that the stability of composition of the alloy layer decreases. Further, the method including the diffusion after the formation of the multilayer film increases the production steps to make the method become complicated. In addition to that, there is a limitation to the uniformity that can be achieved by the diffusion. Thus, the formation of a uniform alloy layer has been difficult.

In other words, under the present circumstances, a single-layer film of a Au/Ag alloy is not used in semiconductor applications as a material that compensates the disadvantages of Au and Ag while enjoying the advantages of the two to the maximum extent.

### DISCLOSURE OF INVENTION

An object of the present invention, in view of the above problems, is to use a single-layer film of a Au/Ag alloy to provide an alloy material that exploits to the maximum extent the properties inherent to single metal films of respective metals and that has a uniform and stable composition and fine workability. It is also an object of the present invention to provide a semiconductor chip using such an alloy material and a production method of the same.

In accordance with the present invention, provided is an alloy material for semiconductors consisting of Au as a main component and Ag in the range of not less than 3 wt % to not more than 40 wt %.

According to the present invention, also provided is a semiconductor chip in which a semiconductor substrate has a metal film formed thereon, the metal film being made of the above-mentioned alloy material.

According to the present invention, further provided is a production method of a semiconductor chip which comprises forming a metal film on a semiconductor substrate using the above-mentioned alloy material.

### BRIEF DESCRIPTION OF DRAWINGS

FIG. 1 is a graph illustrating the relationship between the composition ratio of Ag to a AuAg alloy material and the amount sulfurized and the relationship between the composition ratio of Ag to the AuAg alloy material and the contact resistance;

FIG. 2 is a diagram illustrating the stress of a AuAg alloy film when the film is formed as the alloy material for semiconductors of the present invention on a silicon substrate (defined by the amount of wafer bow);

FIG. 3 is a diagram illustrating the stress of the AuAg alloy film when the film is formed as the alloy material for semiconductors of the present invention on the silicon substrate (defined by the amount of wafer warp);

FIG. 4 is a diagram illustrating the resistance relative to the thickness of the AuAg alloy film when the film is formed as the alloy material for semiconductors of the present invention on the silicon substrate;

FIG. 5 is a diagram illustrating a depth profile determined by Auger analysis of a 200 nm AuAg alloy film (Ag: 25 wt %), which is made of the alloy material for semiconductors of the present invention, after the film is being deposited on a silicon substrate and heated at 300° C. for 40 min.;

FIG. 6 is a diagram illustrating a depth profile determined by Auger analysis of a 200 nm AuAg alloy film (Ag: 25 wt %), which is made of the alloy material for semiconductors of the present invention, after the film is being deposited on a silicon substrate and heated at 380° C. for 40 min.;

FIG. 7 is a diagram illustrating a depth profile determined by Auger analysis of a 200 nm AuAg alloy film (Ag: 25 wt %), which is made of the alloy material for semiconductors of the present invention, after the film is being deposited on a silicon substrate and heated at 420° C. for 40 min.;

FIG. 8 is a diagram illustrating a depth profile determined by Auger analysis of a 200 nm AuAg alloy film (Ag: 25 wt %), which is made of the alloy material for semiconductors of the present invention, after the film is being deposited on a silicon substrate and heated at 470° C. for 40 min.;

FIG. 9 is a diagram illustrating a depth profile determined by Auger analysis of a 200 nm Au film after being deposited on a silicon substrate and heated at 380° C. for 40 min.;

FIG. 10 is a schematic view of a SEM photograph of an outermost surface of a 200 nm AuAg alloy film (Ag: 25 wt %), which is made of the alloy material for semiconductors of the present invention, after the film is being deposited on a silicon substrate and heated at 300° C. for 40 min.;

FIG. 11 is a schematic view of a SEM photograph of an outermost surface of a 200 nm AuAg alloy film (Ag: 25 wt %), which is made of the alloy material for semiconductors of the present invention, after the film is being deposited on a silicon substrate and heated at 380° C. for 40 min.;

FIG. 12 is a schematic view of a SEM photograph of an outermost surface of a 200 nm AuAg alloy film (Ag: 25 wt %), which is made of the alloy material for semiconductors of the present invention, after the film is being deposited on a silicon substrate and heated at 420° C. for 40 min.;

FIG. 13 is a schematic view of a SEM photograph of an outermost surface of a 200 nm AuAg alloy film (Ag: 25 wt %), which is made of the alloy material for semiconductors of the present invention, after the film is being deposited on a silicon substrate and heated at 470° C. for 40 min.;

FIG. 14 is a schematic view of a SEM photograph of an outermost surface of a 200 nm Au film after the film is being deposited on a silicon substrate and heated at 380° C. for 40 min.;

FIG. 15 is a diagram illustrating a depth profile determined by Auger analysis of a 200 nm AuAg alloy film (Ag: 30 wt %), which is made of the alloy material for semiconductors of the present invention, after the film is being deposited on a silicon substrate and heated at 470° C. for 40 min.;

FIG. 16 is a diagram illustrating a depth profile determined by Auger analysis of a 200 nm AuAg alloy film (Ag: 10 wt %) made of the alloy material for semiconductors of the present invention after the film is being deposited on a silicon substrate and heated at 470° C. for 40 min.;

FIG. 17 is a diagram illustrating a depth profile determined by Auger analysis of a 200 nm AuAg alloy film (Ag: 40 wt %), which is made of the alloy material for semiconductors of the present invention, after the film is being deposited on a silicon substrate and heated at 470° C. for 40 min.; and

FIG. 18 is a diagram illustrating the electrical characteristic (leakage current) of a AuAg alloy film made of the alloy material for semiconductors of the present invention when the film is formed as an electrode of a photodiode.

### BEST MODE FOR CARRYING OUT THE INVENTION

An alloy material for semiconductors of the present invention contains Au as a main component and Ag in the range of not less than 3 wt % to not more than 40 wt %. By the term “for semiconductors” is meant that the alloy material is used for constructing semiconductor apparatus such as semiconductor devices, semiconductor chips and the like, or is used in manufacturing processes of the semiconductor apparatus.

The alloy material may be either a solid solution or eutectic alloy such as one in which Au and Ag are uniformly melt or one which is in uniform crystal phase of Au and Ag in which Au and Ag disorderedly occupy the lattice points. However, it is suitable that the alloy material is the solid solution, in particular, a perfect solid solution.

The alloy material containing less than 3 wt % of Ag is not preferable because the effect of suppressing creeping of a Si base decreases. The alloy material containing more than 40 wt % of Ag is not preferable either because there is a possibility that the reliability of the alloy material as an electrode is spoiled in a semiconductor chip.

Ag that constitutes the alloy material for semiconductors preferably is in an amount of not less than 5 wt %, not less than 10 wt %, not less than 15 wt % or not less than 20 wt %. Further, Ag preferably is in an amount of not more than 35 wt %, not more than 30 wt % or not more than 25 wt %. More preferably, Ag is in an amount of not less than 10 wt % and not more than 30 wt %.

However, where the proportion of Ag needs to be small and the AuAg alloy is to be formed as a thin film directly on a silicon substrate, the amount of Ag is more preferably not less than 10 wt % so as not to reduce the effect of suppressing the silicon diffusion and is more preferably not more than 30 wt % so as to suppress the effect of sulfuration and a shift in electrical characteristics due to an increase in contact resistance.

Although it depends on the application, Au and Ag, when used in semiconductor chips, respectively have a purity of 3N (99.9%) or higher, more preferably a purity of 4N or higher and even more preferably a purity of 5N or higher in order not to spoil the electrical characteristics such as leakage current and to secure the reliability of the chips.

The alloy material for semiconductors of the present invention may be manufactured by known methods, for example, a method of melting ingots of Au and Ag by high-frequency melting to form an alloy and a method of mixing Au powder with Ag powder and heating the mixture to form an alloy.

Thus, the alloy material for semiconductors of the present invention significantly alleviates various problems associated with the use of Au by itself, for example, diffusion of a Si base when a film is formed directly on a Si layer. This allows a stable film composition with no Si diffusion to be maintained, thereby improving the weatherability and the metal strength.

The alloy material for semiconductors of the present invention may be used in various applications. Examples of these applications include electronic hardware, electronic components, electro-optical components, and more specifically, semiconductor devices and semiconductor chips including wires, electrodes, bumps, light-shielding films, contacts or wires via metal paste (such as light-transmission units, light-receiving units for remote controllers, PC/GP unit, DRAMs, flash memories, CPUs, MPUs, ASICs, LSIs, TFTs, semiconductor lasers, solar cells, light-emitting elements, CCDs, thyristors, photodiodes, phototransistors, power transistors and the like), and liquid-crystal display panels (a flat panel displays, reflective and translucent liquid-crystal display panels and the like). Typically, the alloy material of the present invention may be used in the form of a sputtering target material, a vapor-deposition material or a wire material for bonding.

The thickness of the alloy material is not particularly limited when used in the above hardware and components, but in one example, the alloy material is preferably used with a thickness in the range of 50 nm to 1000 nm, inclusive, in view of the stress of the alloy film. If the film stress increases, there may be manufacturing problems such as a probe not being able to appropriately contact a wafer at the time of wafer test. Where the wafer test is not required or the film is used in the subsequent formation of a bump or plating, the thickness of the alloy film may be freely set.

The alloy material for semiconductors of the present invention may be used in the form of a metal film formed on a semiconductor substrate by various methods. For example, the alloy material is flexibly and widely applicable to existing semiconductor processes and the like such as sputtering, vapor-deposition, plating and bonding techniques.

More specifically, in the vapor-deposition technique, for example, the alloy material as a AuAg alloy wire having a diameter of 1 mm is set in a crucible and then heated while a vacuum degree of about 3×10⁻⁶ Torr is maintained to form a AuAg alloy film having a uniform composition.

In the plating technique, for example, an alkaline cyanogen bath and the AuAg alloy are used at a temperature of about 25° C. and a current density of about 0.5 A/dm² to make a AuAg alloy film deposited.

In the bonding technique, an ingot of AuAg alloy is formed by melting and casting, and extrusion and elongation of the ingot are repeated to eventually form a thin wire having a diameter of about 20-30 μm. Specifically, the alloy wire may be used in the form of a bonding wire formed for connecting electrodes on a semiconductor chip and outside electrodes on a lead frame.

Where the AuAg alloy material is to be patterned for use as a wire, electrode, bump or the like, the alloy material can easily be etched not only by a lift-off technique, but by using, in accordance with the composition of the AuAg alloy material, an aqueous potassium iodide solution or a mixed solution of an aqueous potassium iodide solution and an etching solution containing phosphoric acid.

By forming the AuAg alloy in an appropriate size and at an appropriate position, two or more kinds of a wire, electrode, bump, light-shielding film, contact and the like, for example, a combination of wire and electrode, of light-shielding film and electrode, of bump and electrode and of wire and contact can be formed in the same step.

The alloy material for semiconductors of the present invention, regardless of which technique such as sputtering and vapor-deposition is used, presents the same resistance, stress, elongation, strength and the like and can easily and surely form a film.

In the present invention, it is preferable that after forming a metal film of the AuAg alloy material on, for example, a semiconductor chip, a semiconductor substrate, a semiconductor layer (of element semiconductor such as silicon, germanium, or of compound semiconductor such as GaAs, for example) or the like, a heating treatment is performed at a temperature in the range of 300° C. to 520° C., inclusive.

By doing so, a stable contact with the semiconductor layer (such as of silicon) can be secured. For example, where Al or an AlSi alloy, which is common as a metal for an electrode on the semiconductor substrate side, is used and the AuAg alloy is used as a rear electrode, Al spiking (the phenomenon in which Al penetrates into the semiconductor substrate) and an increase in resistance at the contacts can be prevented.

Particularly when forming the AuAg alloy on a silicon layer, it is preferable that a heating treatment is carried out at a temperature in the range of 300° C.-470° C. in order to suppress eutectic crystallization of Au—Ag—Si and not to degrade the characteristics of a semiconductor chip or the like. In this temperature range, the creeping of the Si base to the AuAg alloy, the alloying reaction of the Si base and AuAg, and the formation of an oxide on the outermost layer of the AuAg alloy are suppressed; that is, the uniform composition of the AuAg alloy film does not change even after the heating and the composition of the film is stable against heat, allowing the AuAg alloy film to be thinner for use. This improves the bonding strength of a chip die bond surface or wire bond surface and gives excellent compatibility with metal paste, whereby various components and devices with high reliability can be provided.

### EXAMPLES

An alloy material, a semiconductor chip and a production method of the chip according to the present invention will hereinafter be described in detail.

### Example 1

### Production of Alloy Material

Ingots of Au and Ag were weighed so that Au and Ag were in various proportions, and after melting the ingots by high-frequency melting, Au and Ag were poured into molds to prepare AuAg alloy materials. Au and Ag having a purity of 4N were used as a material.

The obtained alloy materials of various compositions were formed into specimens each having a size of about 50×20×1, and the specimens were left standing at 60° C. in a 90 mmHg, H₂S atmosphere for 10 days. The specimens were then each measured for the relationship between the composition of the specimen and the amount sulfurized and for the relationship between the composition of the specimen and the contact resistance. The contact resistance of each specimen before and after the sulfuration test was measured by a four-terminal method. An increase in amount sulfurized was determined from the weights of the specimen before and after the sulfuration test using a precision balance.

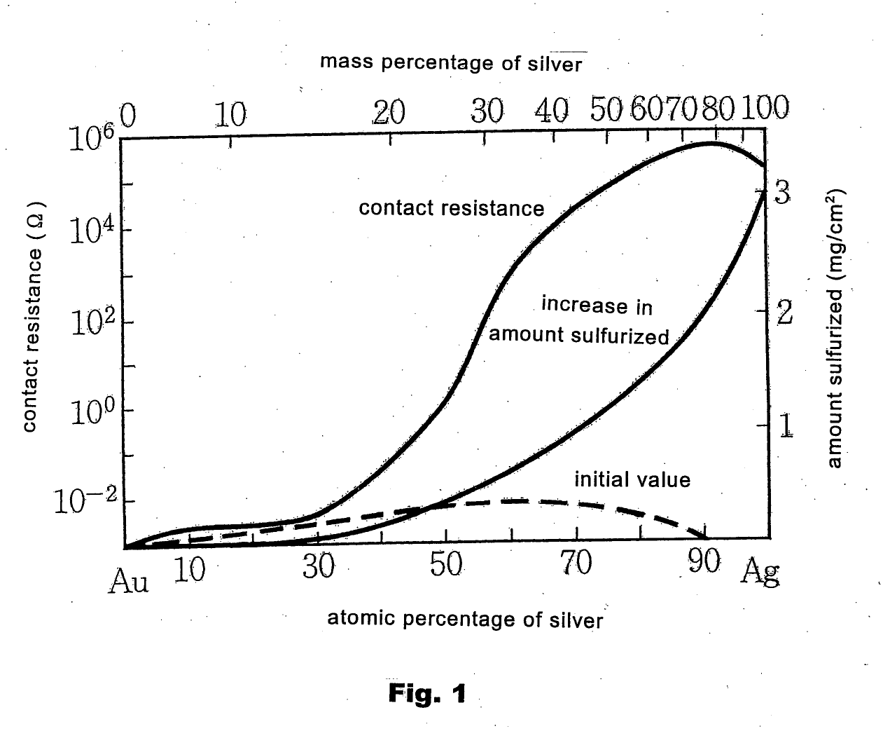

The results are shown in FIG. 1.

From FIG. 1, it is apparent that the amount sulfurized increased as the weight percent of Ag increased and that the change over time in the surface of the alloy material was greater than that in the surface of a Au material. It is also found that as the weight percent of Ag increased, the contact resistance greatly increased relative to the initial value (the contact resistance of the AuAg alloy before the sulfuration test), and thus there was a possibility that the reliability of the alloy as an electrode in a semiconductor chip was spoiled.

On the other hand, it is found that where the weight percent of Ag was small, the effect of suppressing the creeping of a Si base was small.

### Example 2

### Production of Alloy Material

7.5 kg of a Au ingot having a purity of 4N and 2.5 kg of a Ag ingot having a purity of 4 N were put into a crucible and melted by high-frequency melting. Au and Ag were then poured into a mold to prepare an ingot having a Au—Ag ratio of 75 wt %-25 wt %. The AuAg alloy material thus obtained enjoyed the workability of Au and the elongability of Ag.

The obtained ingot was rolled to form a plate of 8 mm thickness. The plate was formed into a disc of 250 mm diameter on a lathe and was bonded to a backing plate made of Cu to prepare a target of AuAg alloy. For comparison, a Au target and a Ag target were prepared in the same manner as the AuAg alloy target.

### Example 3

### Production of Alloy Material

AuAg alloy targets were prepared in the same manner as in Example 2 except that the ratios of Ag were set to 3 wt %, 10 wt % and 40 wt %.

### Example 4

### Formation of Alloy Film

Using the targets prepared in Example 2, a AuAg alloy film, Au film and Ag film each having a thickness of about 100 nm-1000 nm were formed as single metal film layers respectively on silicon substrates by a sputtering apparatus.

The sputtering apparatus was of horizontal type (face-up system) and it included, as independent reaction chambers, a reverse-sputtering chamber for cleaning the surface to be sputtered and a sputtering chamber in which the AuAg alloy target, Au target and Ag target were placed. A target electrode included a double pole electromagnet cathode.

The sputtering conditions were set such that the pressures inside the reaction chambers were in the range of 2 mTorr-9 mTorr and the DC power was in the range of 0.3 kW−1 kW.

The alloy film thus formed contained 27.5 wt % of Ag and 72.5 wt % of Au according to the fluorescent X-ray composition analysis, and was a uniform film. The film had a slightly larger Ag proportion than the alloy material probably because Ag whose mass number was smaller than that of Au was easier to be scattered by sputtering and the sputtering rate of Ag was fast.

The AuAg alloy film, in comparison to the single film of Au or Ag, had a little dependence on the pressure and DC power at the sputtering. Thus, no great change in composition of the film was observed after the formation thereof, and a uniform film was formed.

The film stress of the alloy film and the metal films after the sputtering, and the film stress and resistance of the alloy film and the metal films after heating (at 380° C. for 40 min.) under a nitrogen atmosphere were measured.

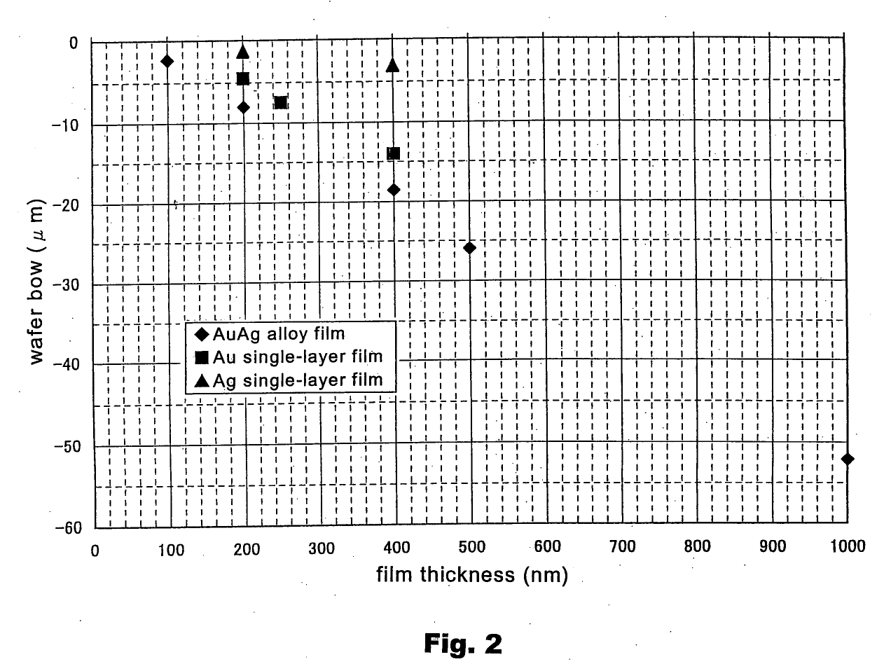

The obtained results are shown in FIGS. 2-4. The film stress was defined by bow and warp of the semiconductor substrates before and after the film formation or after the heating. The measurements of the resistances were conducted at room temperature by a four-probe method.

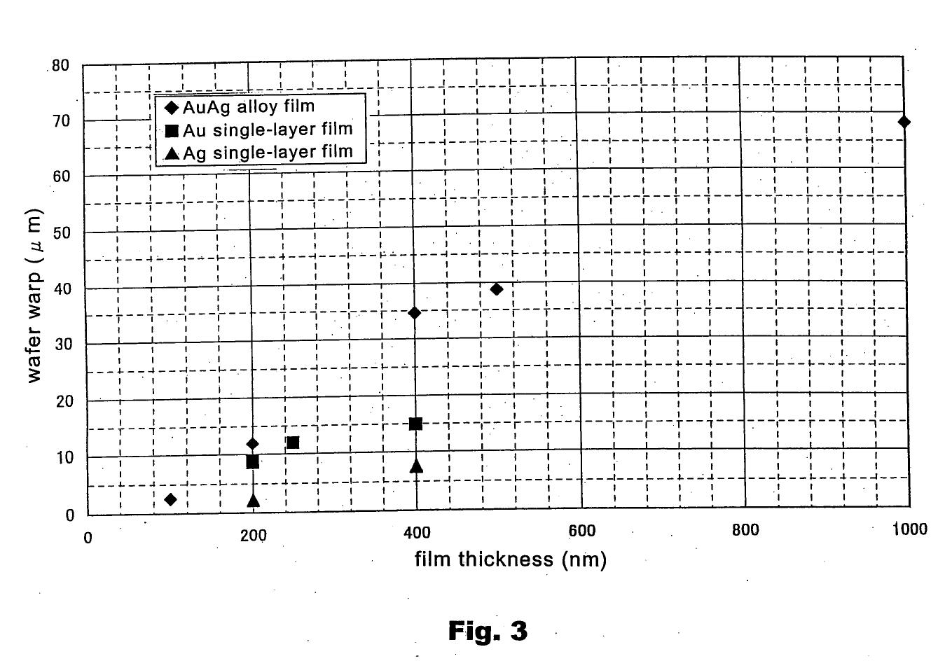

FIGS. 2 and 3 show that the AuAg alloy film had a tendency to slightly increase in the amount of bow and warp of the wafer when compared to the Au film of the same thickness. However, no great difference was found between the two films and it is shown that the alloy film was at a level where it can sufficiently withstand practical use.

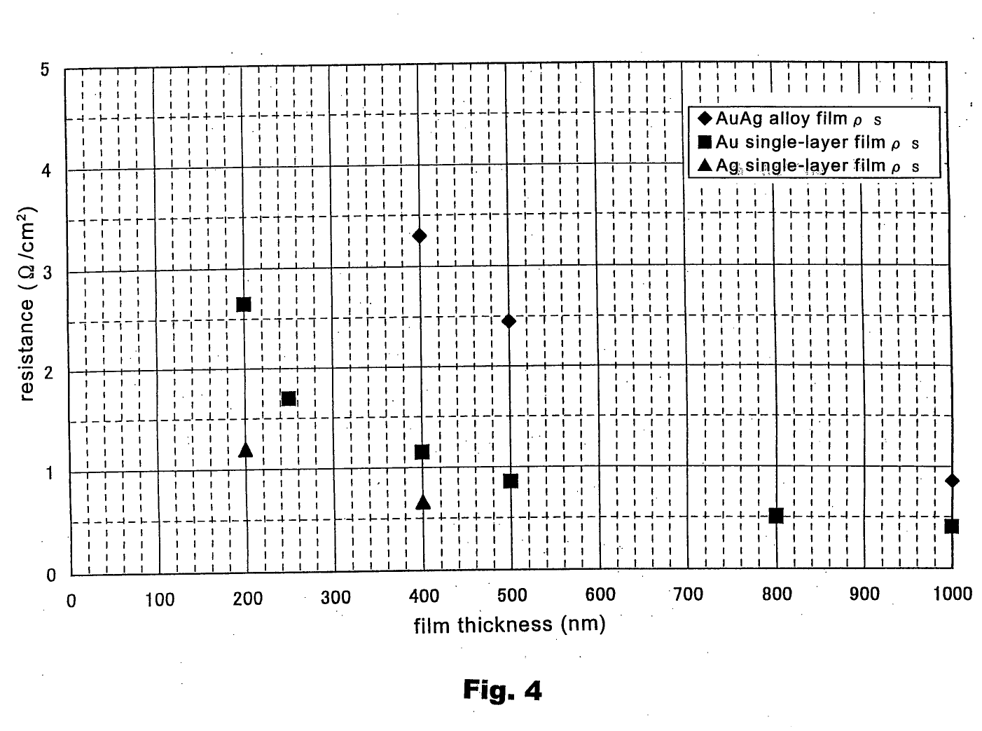

FIG. 4 shows that the AuAg alloy film has a tendency to slightly increase in resistance when compared to the Au film of the same thickness. However, no great difference is found between the two films and it is shown that the alloy film is at a level where it can sufficiently withstand practical use.

These results show that both the film stress and resistance of the AuAg alloy film were at a level where the film could be utilized in semiconductor chips.

### Example 5

### Formation of Alloy Film

Using the materials prepared in Example 2, AuAg alloy films each having a thickness of 200 nm and Au films each having a thickness of 200 nm were respectively formed on silicon substrates by sputtering in the same manner as in Example 4. Under a nitrogen atmosphere, the films were heated at 300° C., 380° C., 420° C. and 470° C. respectively for 40 min. The Auger analysis was carried out from the outermost surface side of each film, and the condition of the outermost surface was observed with an electron microscope.

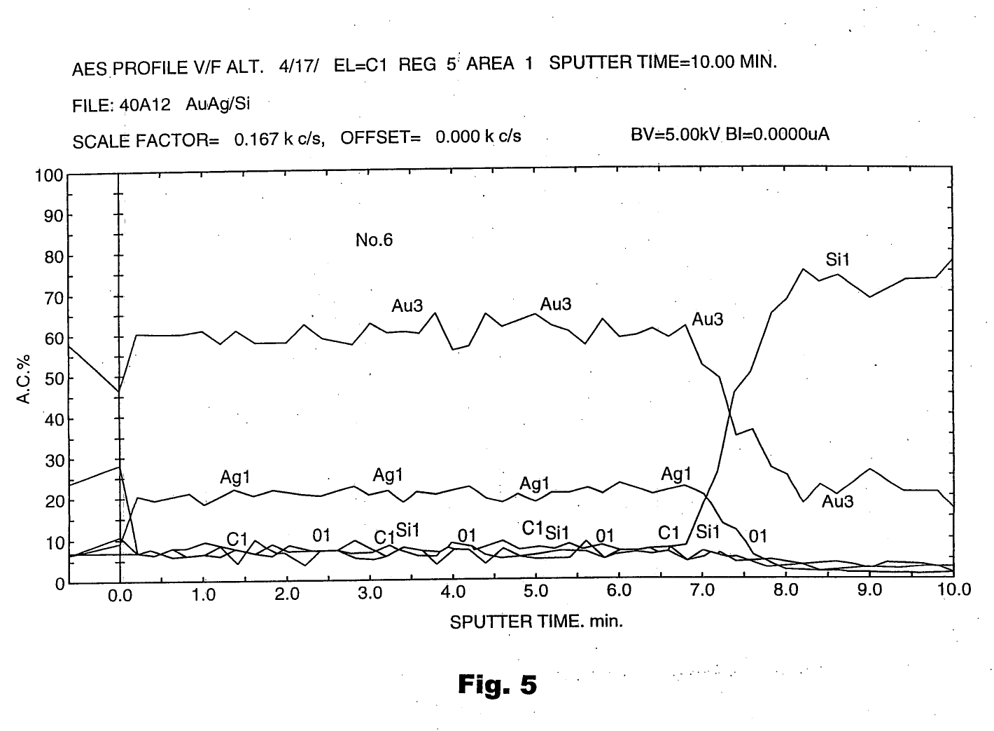

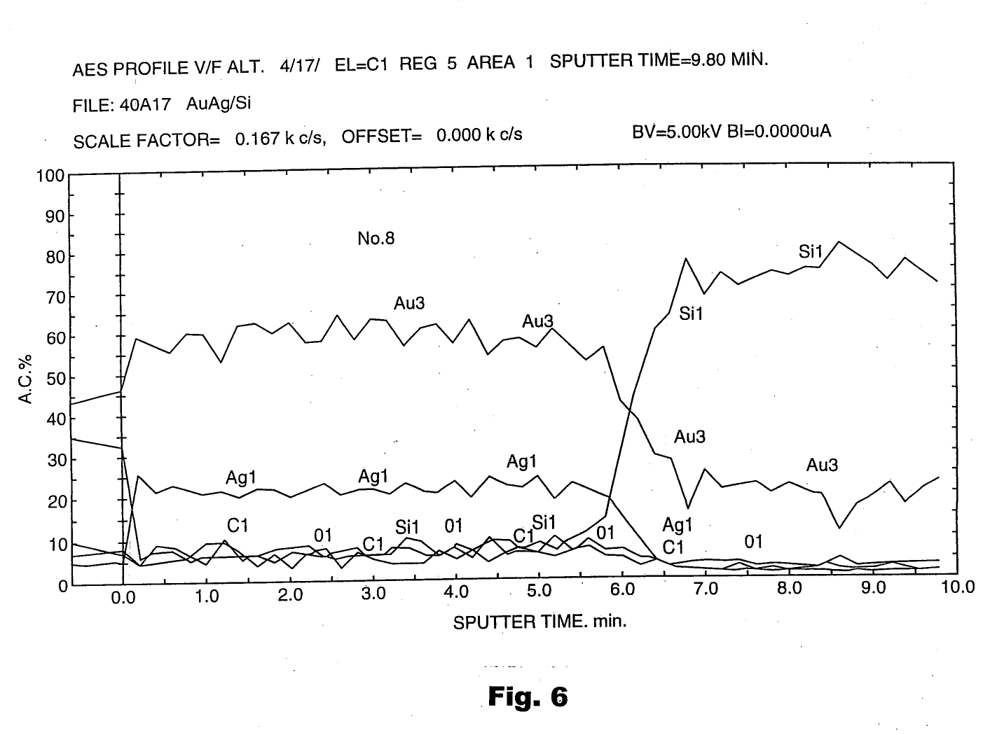

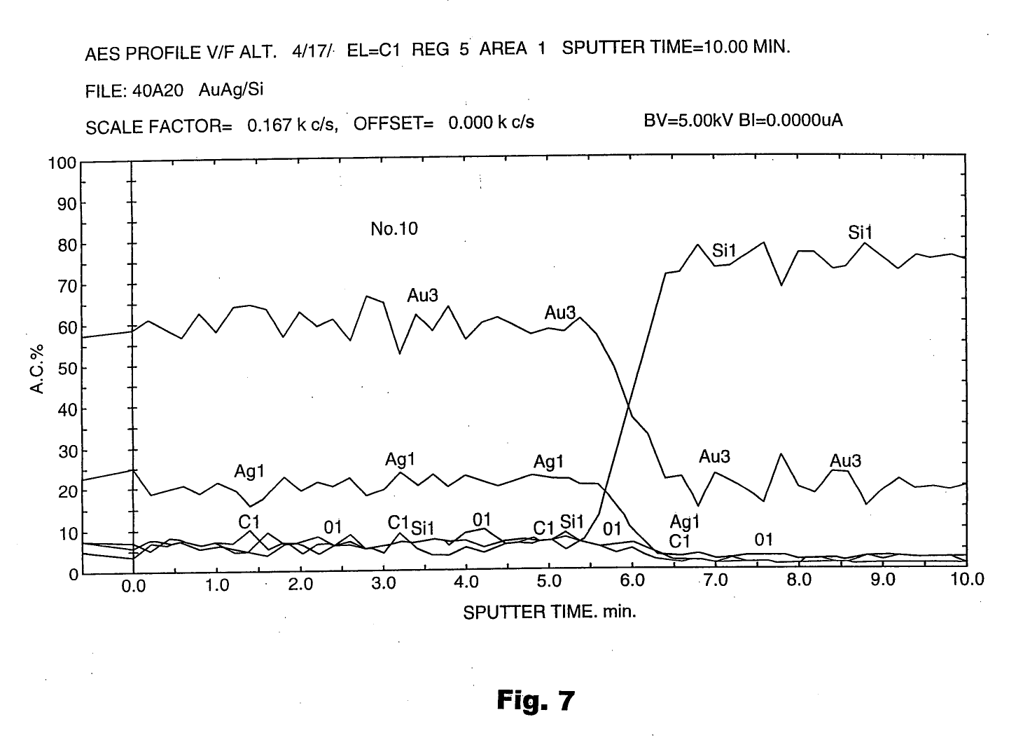

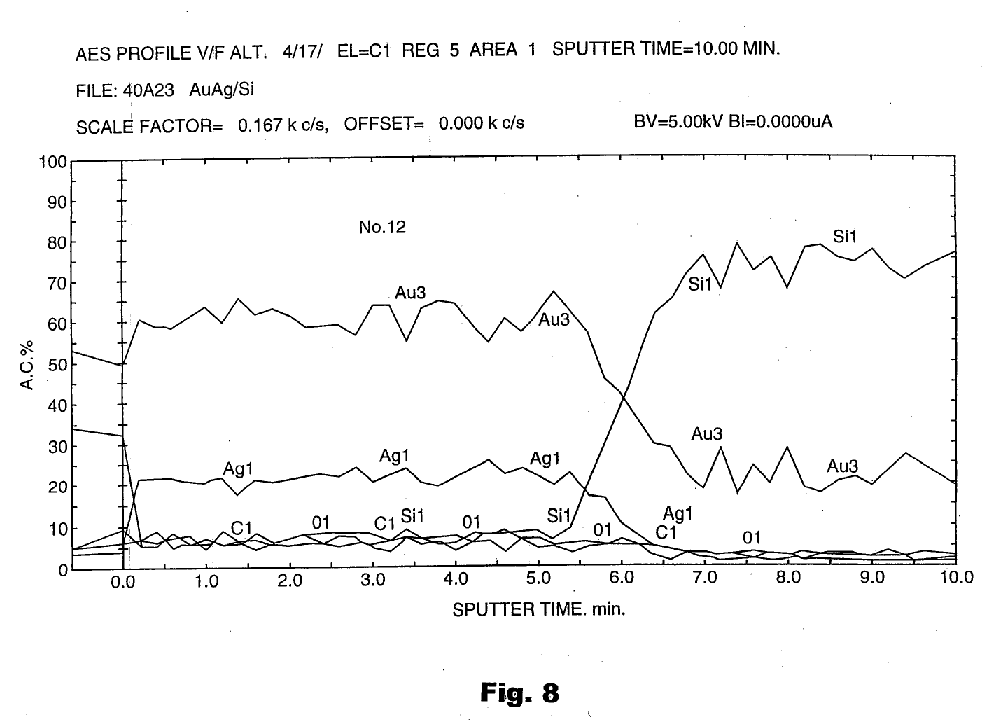

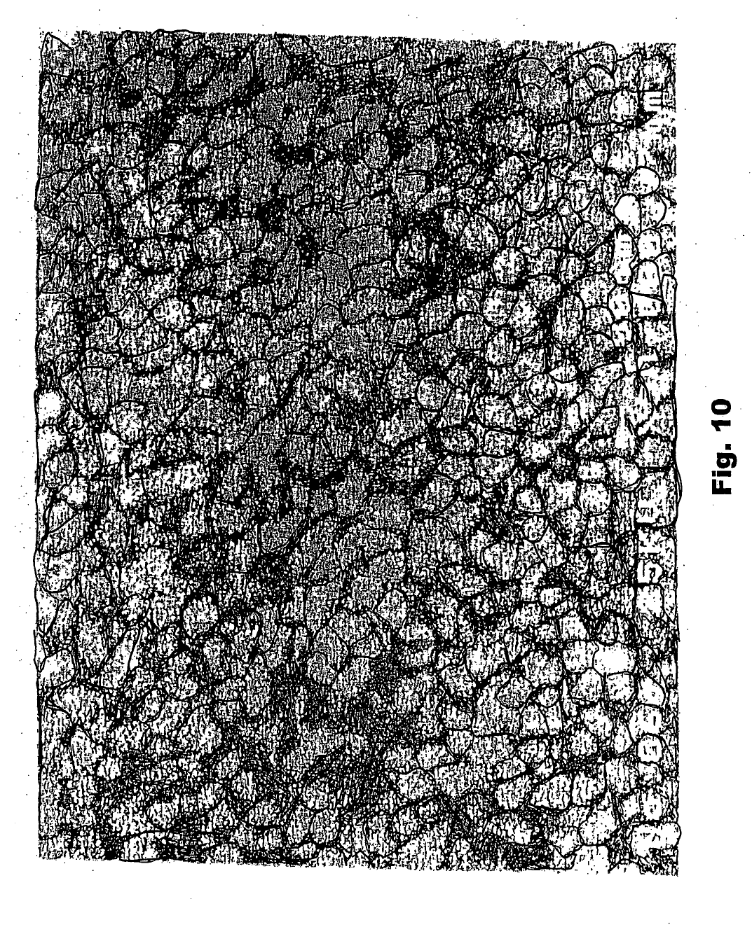

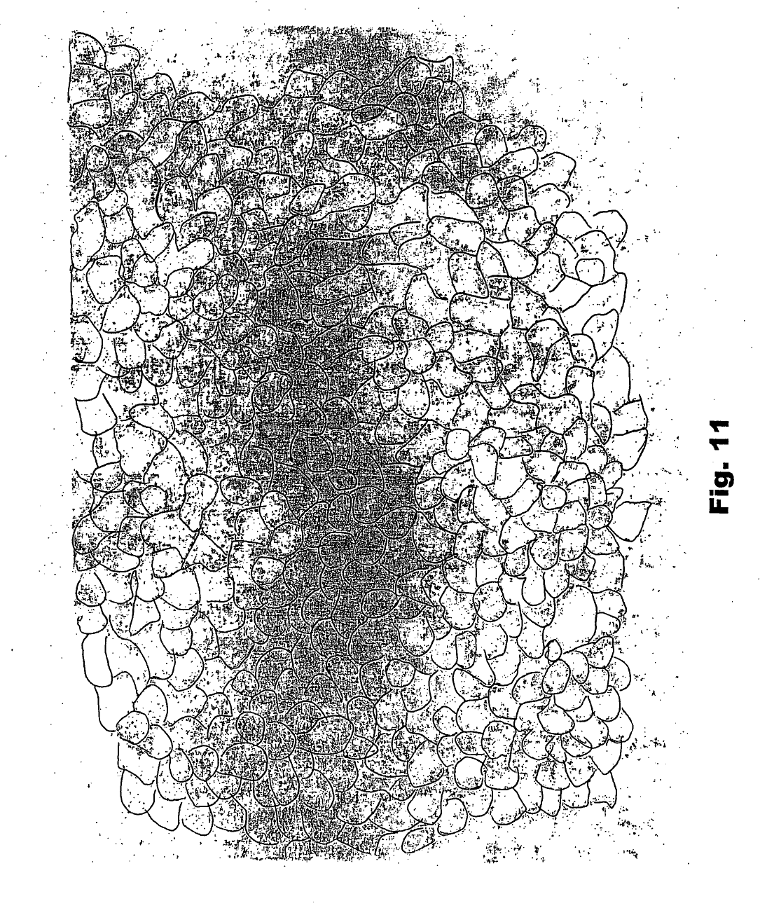

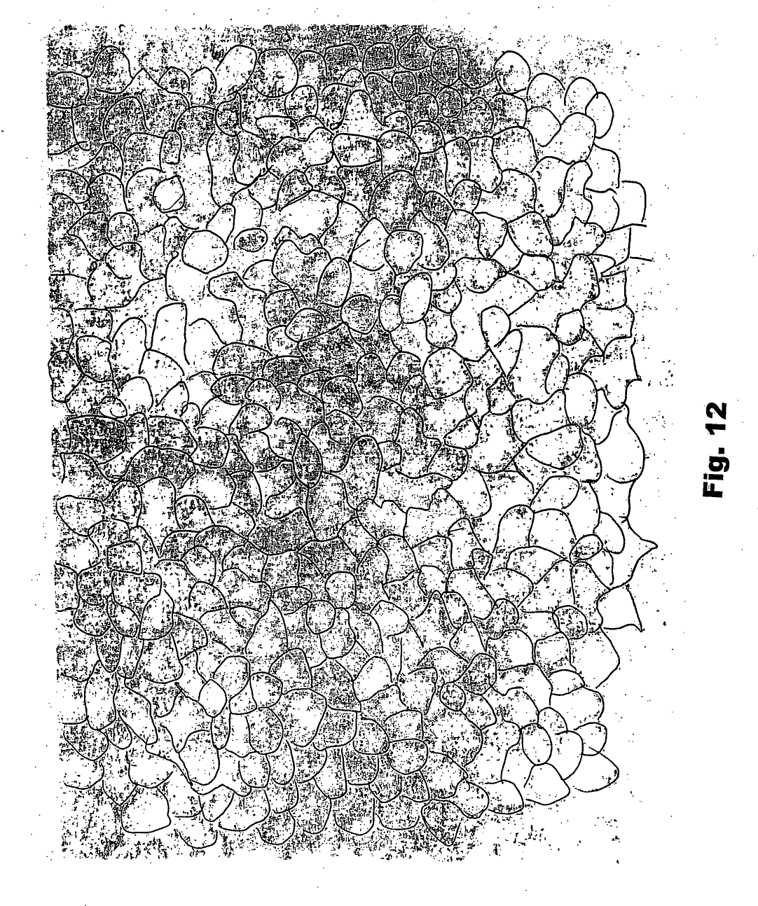

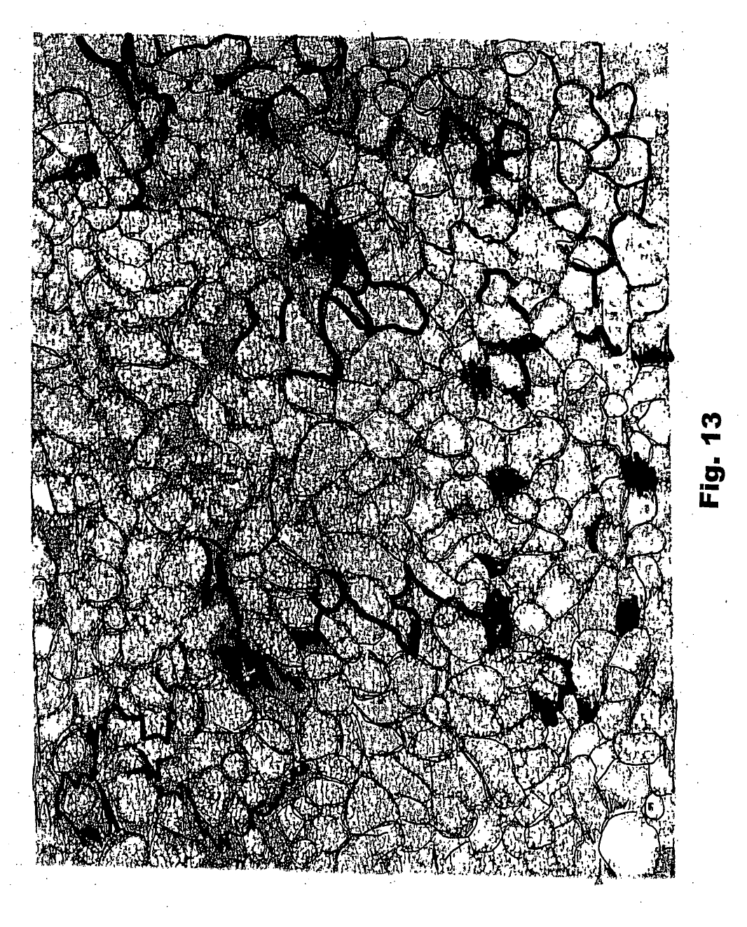

The results of the analyses and observations are shown in FIGS. 5-9 and FIGS. 10-14, respectively. In FIGS. 5-8 and FIGS. 10-13, it is shown that the concentrations of Si and O remained constantly at low level from the outermost surface to a certain depth. This indicates that the AuAg alloy hardly underwent the penetration of a Si base, that is, the alloying reaction of the AuAg alloy and silicon took place only in an area within less than 50 nm from the interface between AuAg and silicon. It is also shown that the amount of oxygen in the film surface was small and the film was uniform with no great changes in condition of the film surface. These results indicate that the AuAg film can be used as a film thinner than the film made of Au alone.

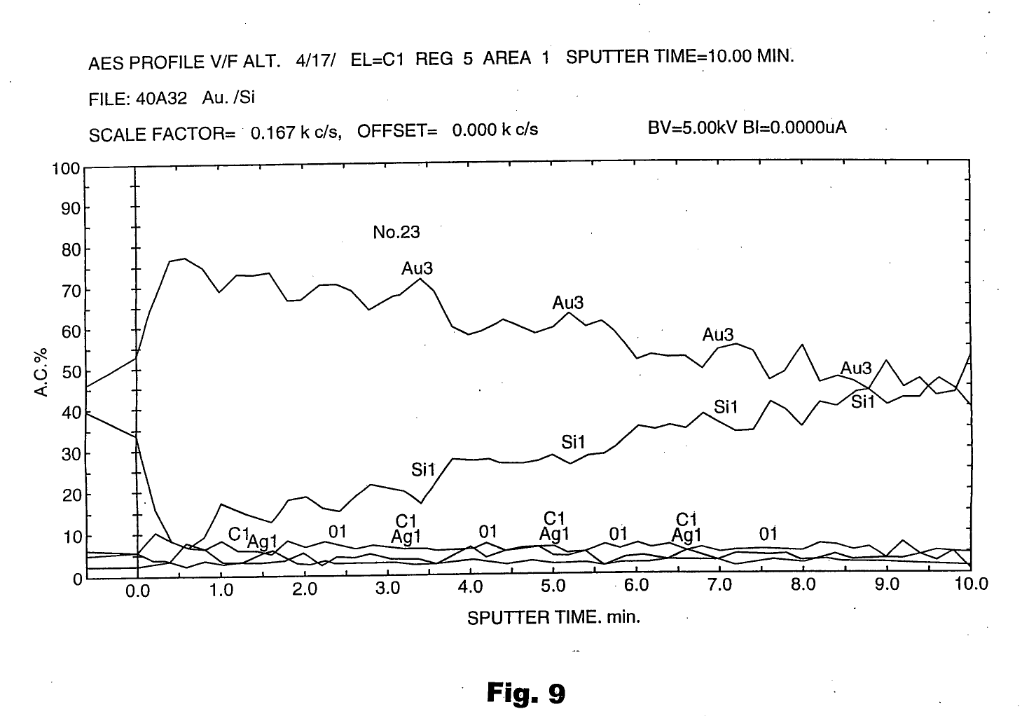

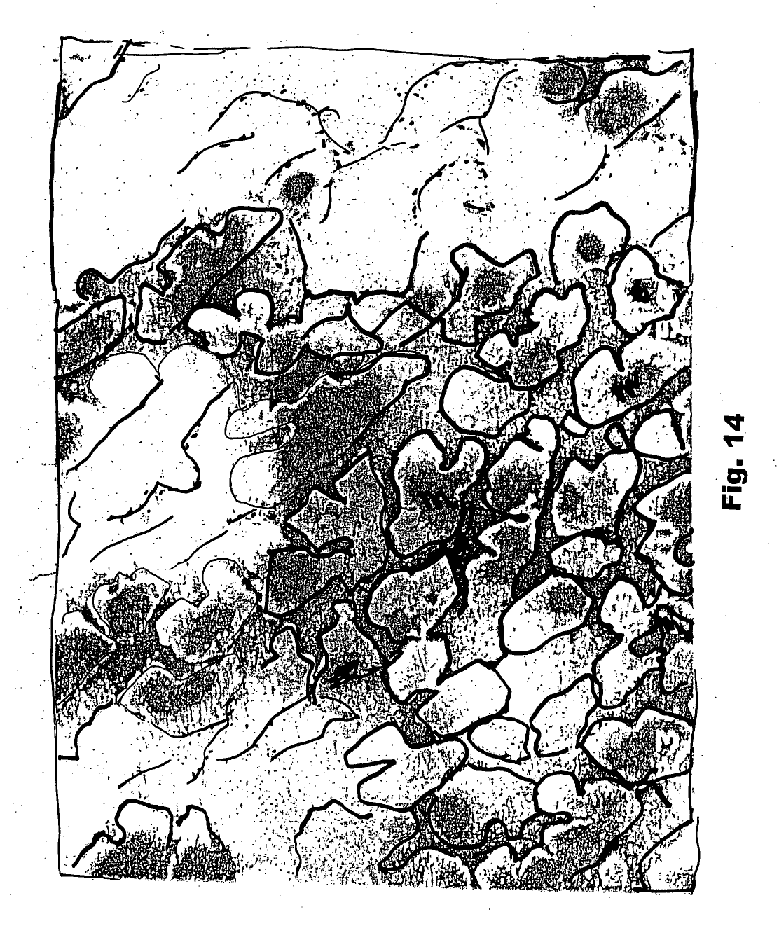

In FIGS. 9 and 14, on the other hand, it is shown that silicon was creeping to the surface of the Au film due to the heating treatment, whereby the alloying (eutectic) reaction of silicon and Au was accelerated. There is also shown that the amount of oxygen detected in the surface of Au film was higher than that detected in the surface of AuAg alloy film.

### Example 6

### Formation of Alloy Film

Using the targets prepared in Example 3, three kinds of 200 nm thick AuAg alloy films having different Ag proportions were respectively formed on silicon substrates using the sputtering apparatus as in Example 4.

The compositions of the obtained AuAg alloy films were analyzed using fluorescent X-rays. The results are shown in Table 1.

TABLE 1

| | |
|---|---|
| Target | AuAg Alloy Film |

| No. | Au (wt %) | Ag (wt %) | Au (wt %) | Ag (wt %) |
|---|---|---|---|---|
| 1 | 97 | 3 | 96.6 | 3.4 |
| 2 | 90 | 10 | 88.8 | 11.2 |
| 3 | 60 | 40 | 65.3 | 34.7 |

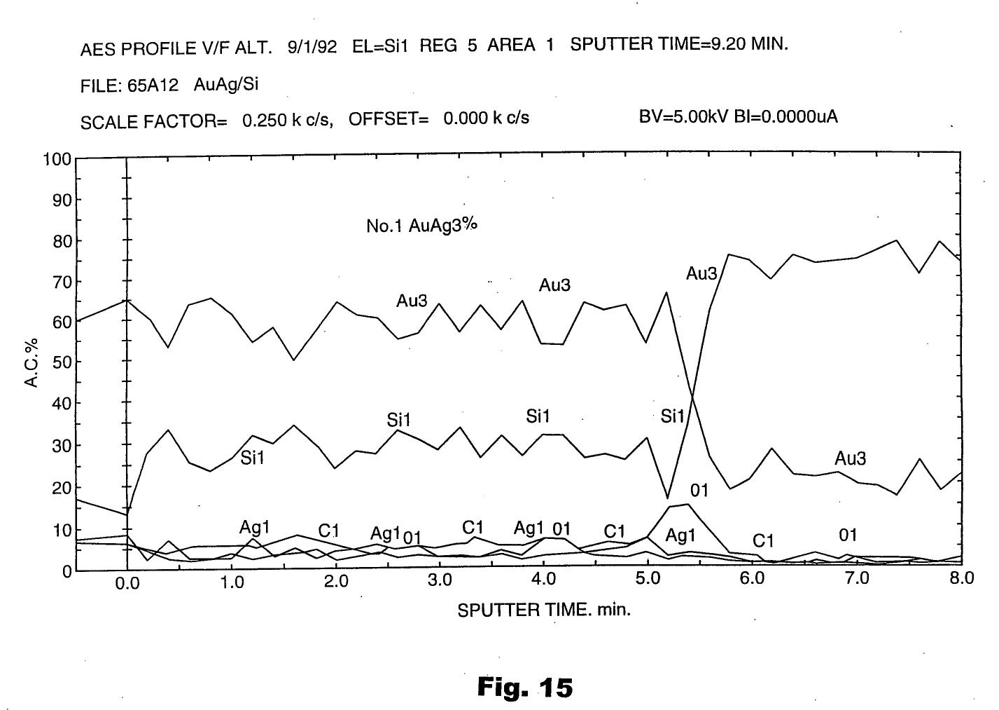

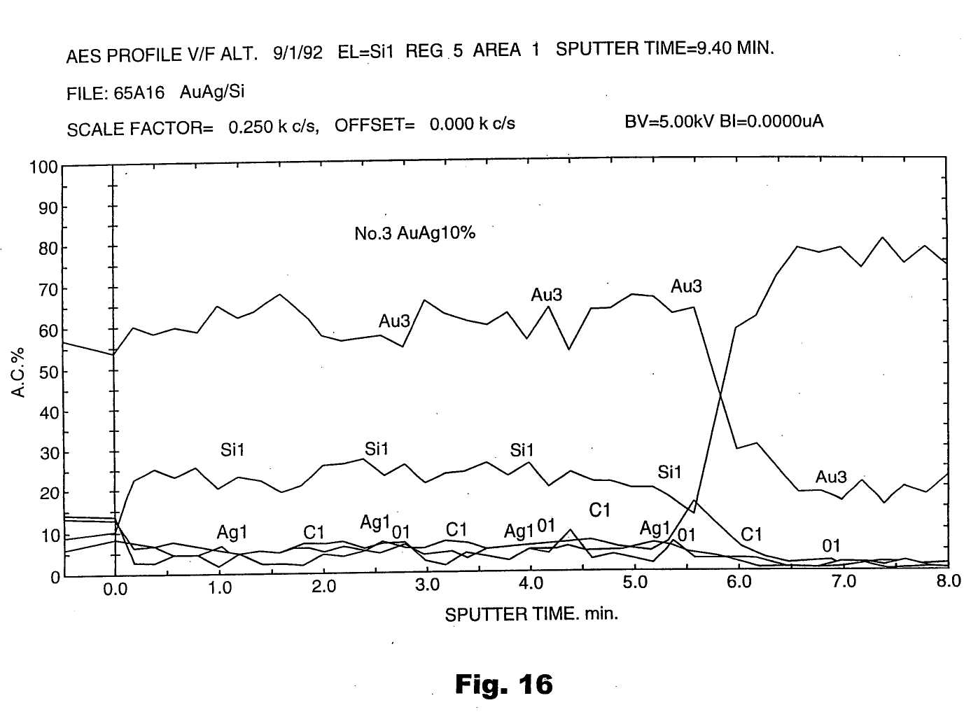

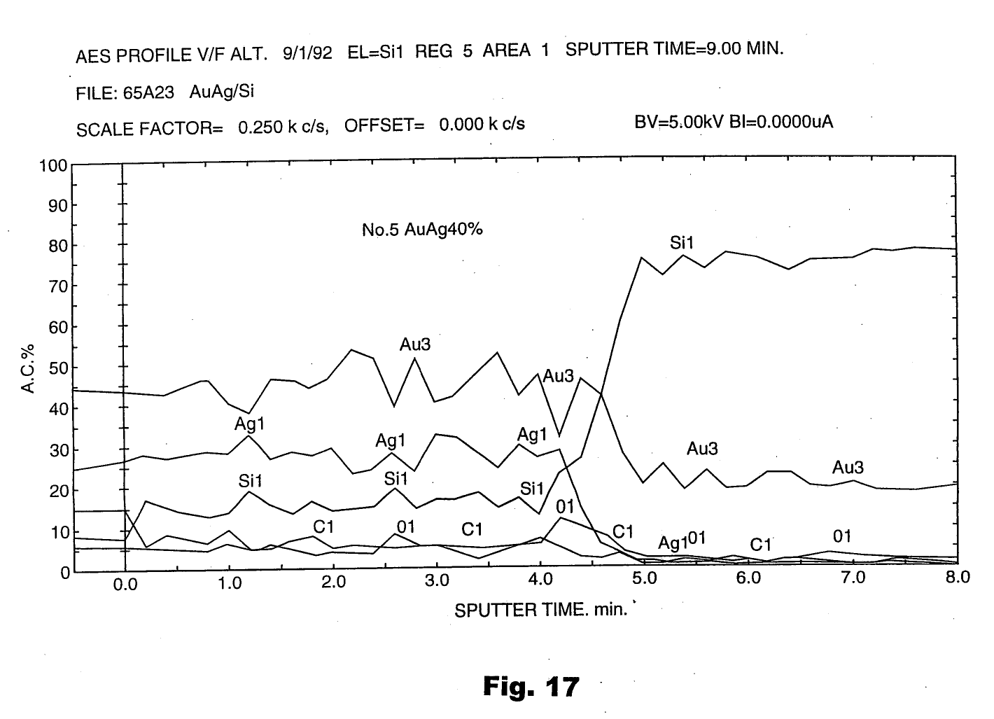

The obtained alloy films were heated at 450° C. for 40 min. under a nitrogen atmosphere, and the Auger analysis was performed from the outermost surface side of each film. The results are shown in FIGS. 15-17.

FIGS. 15-17 show that the AuAg alloy film in any of the above proportions suppressed the creeping of silicon and that oxygen was not detected in the outermost surface of the film.

### Example 7

### Semiconductor Chip

Using the target prepared in Example 2, electrodes composed of a AuAg alloy film (200 nm) were formed on semiconductor chips made of silicon in the same manner as in Example 4. The electrodes were heated at 380° C. for 40 min. under a nitrogen atmosphere, and the bonding strengths of the electrodes composed of the AuAg alloy film to the semiconductor chips were measured.

The results are shown in Table 2. The strength was measured by applying a pressure from the sides of the chip and using a tension gauge. The chips each cut into a size of 0.6 mm×0.6 mm and die bonded with a Ag paste were used for evaluation.

TABLE 2

| | Average Value of Die | Number of Measured |
|---|---|---|
| | Bond Strength | Electrodes |
| Electrodes of AuAg | 500 g | 100 |
| Alloy Film | | |
| Electrodes of Au | 495 g | 50 |
| Film | | |

Table 2 shows that the electrodes made of the AuAg alloy film were equal to or stronger than the electrodes made of the Au film in bonding strength. It is also confirmed from the destructive test that the die bond interface was stronger in strength than the chip itself.

### Example 8

### Semiconductor Chip

A photodiode was fabricated as an optical semiconductor chip. The photodiode was fabricated by: patterning (a surface of) a semiconductor substrate; forming an anode layer; using the AuAg alloy target prepared in Example 2 to form a 200 nm AuAg alloy film on a rear surface of the semiconductor substrate by the forming method shown in Example 4; and heating at 380° C. for 40 min. under a nitrogen atmosphere to form a cathode electrode.

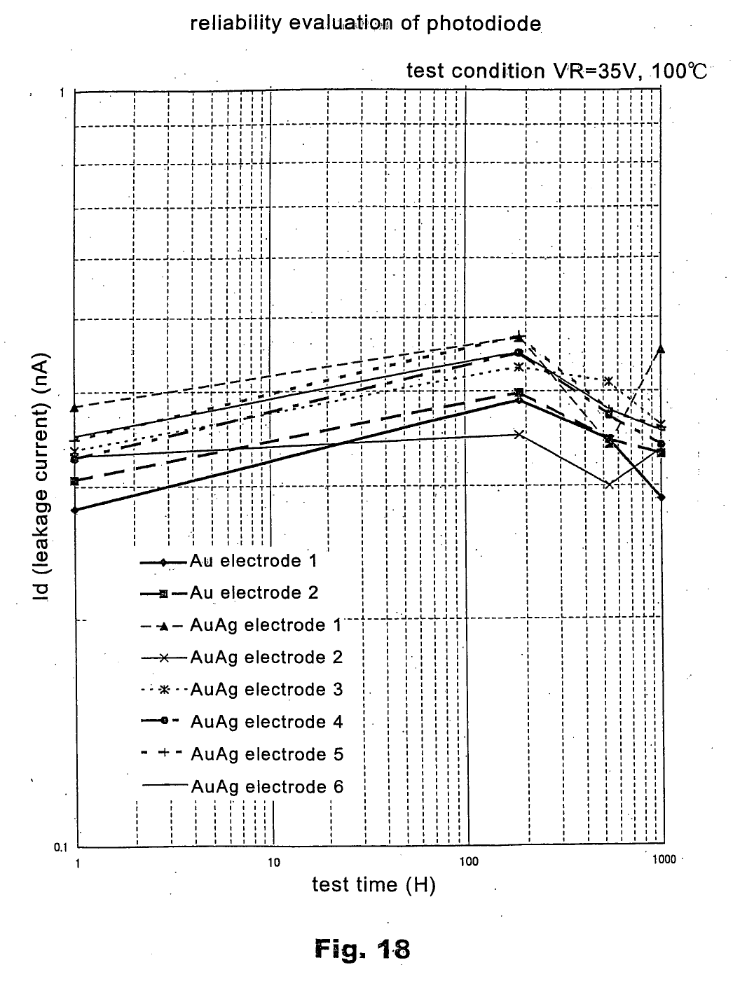

The electrical characteristic and reliability of the photodiode were determined from the leakage current of the electrode made of the AuAg alloy material while applying a reverse voltage of 35 V and heating to 100° C. The results are shown in FIG. 18. The short-circuit current (Isc) of the photodiode was also measured.

It is found from the results that, in comparison to a photodiode using a Au film, the photodiode using the AuAg alloy film had no great characteristic shifts or variations in both leakage current and short-circuit current and that the photodiode had no problem in terms of practical use.

Further, the yield of good photodiodes using the AuAg alloy film was about the same as that of good photodiodes using the Au film.

### Example 9

### Semiconductor Chip

A phototransistor was fabricated as an optical semiconductor chip. The phototransistor was fabricated by: patterning (a surface of) a semiconductor substrate; forming a base-emitter layer; using the AuAg alloy target prepared in Example 2 to form a 200 nm AuAg alloy film on a rear surface of the semiconductor substrate by the forming method shown in Example 4; heating at 380° C. for 40 min. under a nitrogen atmosphere to form a collector electrode.

The Collector-Emitter saturation voltage VCE (sat) and the Collector-Emitter breakdown voltage (BVCEO) were measured using the phototransistor.

It is found from the results that, in comparison to a phototransistor using a Au film, the phototransistor using the AuAg alloy film had no characteristic shifts or variations in Collector-Emitter saturation voltage VCE (sat) and Collector-Emitter breakdown voltage (BVCEO), and that the phototransistor had no problem in terms of practical use.

Further, the conduction tests and temperature cycling test for checking the reliability of the film as the electrode were carried out, and fine results were obtained in both tests.

The conduction tests were conducted at room temperature (25° C.) and at high-temperature (at 85° C.). As the measurement conditions, the forward currents (IF) were set to 50 mA (at 25° C.) and 30 mA (at 85° C.), respectively and the Collector-Emitter electric power (Pc) were set to 150 mW (at 25° C.) and 70 mW(at 85° C.), respectively. The temperature cycling test was conducted by repeating the temperatures of −55° C. and 120° C. for 30 min. each.

### Example 10

### Semiconductor Chip

A phototriac was fabricated as a semiconductor chip. The phototoriac was fabricated by: patterning (a surface of) a semiconductor substrate; forming a base-emitter layer; using the AuAg alloy target prepared in Example 2 to form a 200 nm AuAg alloy film on a rear surface of the semiconductor substrate by the forming method shown in Example 4; heating at 380° C. for 40 min. under a nitrogen atmosphere to form a collector electrode.

The holding current (IH), on-state voltage (VT), minimum trigger current (IFT) and repetitive peak-off state voltage (VDRM) were measured using the phototriac.

It is found from the results that, in comparison to a phototriac using a Au film, the phototriac using the AuAg alloy film had no characteristic shifts or variations in holding current, on-state voltage, minimum trigger current and repetitive peak-off state voltage, and that the phototoriac had no problem in terms of practical use.

In accordance with the present invention, used is an alloy material consisting of Au as a main component and Ag in the range of not less than 3 wt % to not more than 40 wt %, so that the material has a stable composition and properties such as resistance can be stabilized in comparison to a metal material made of Ag alone. Further, the AuAg alloy material can minimize the change in composition before and after heating.

Particularly where Au and Ag each have a purity of 3N or higher, degradation in electrical characteristics caused by impurities can be prevented and a metal material of superior quality can be provided.

By using the alloy material for semiconductors of the present invention in the form of a sputtering target material or a vapor-deposition material and a bonding wire material, techniques that are conventionally used can be applied without the need of any special equipment.

Since the AuAg alloy is a noble metal, recovery and recycle thereof are easier than those of other metal materials, which allows it to be environmentally friendly.

Where the alloy material for semiconductors of the present invention is formed as metal films to construct semiconductor chips and the like, the optical and electrical characteristics of electronic equipment, electronic components and the like can be improved to realize more reliable electronic equipment, electronic components and the like. Further, the alloy material is excellent in workability, and it can improve the yield of the equipments and components. In addition, because Ag is cheaper than Au, the alloy material can provide cheaper electronic equipment and components than Au alone.

1. An alloy material for semiconductors, the alloy material directly covering a Si semiconductor, the alloy material consisting of Au as a main component and Ag in the range of not less than 3 wt % to not more than 40 wt %.

2. An alloy material as set forth in claim 1, wherein Au and Ag have a purity of 3N or higher.

3. An alloy material as set forth in claim 1, wherein the alloy material is in the form of a sputtering target material, a vapor-deposition material and a bonding wire material.

4. A semiconductor chip in which a semiconductor substrate has a metal film formed thereon, the metal film being made of an alloy material of claim 1.

5. A semiconductor chip as set forth in claim 4, wherein the metal film has a thickness in the range of 50 nm to 1000 nm, inclusive.

6. A semiconductor chip as set forth in claim 4, wherein the metal film is formed as a wiring, an electrode, a bump or a light-shielding film.

7. A semiconductor chip as set forth in claim 4, wherein the metal film is formed via a Ag paste.

8. A production method of a semiconductor chip which comprises forming a metal film on a semiconductor substrate using an alloy material of claim 1.

9. A production method as set forth in claim 8, wherein the alloy material is formed into the metal film by sputtering or vapor deposition.

10. A production method as set forth in claim 8, wherein after the formation of the metal film, heating is carried out at a temperature in the range of 300° C. to 520° C., inclusive.
